(19) United States
(12) Patent Application Publication
(10) Pub. No.: US 2025/0360598 A1
(43) Pub. Date: Nov. 27, 2025

(54) METHOD OF MANUFACTURING GRINDSTONE, GRINDSTONE, METHOD OF MANUFACTURING DRESSER BOARD, AND DRESSER BOARD

(71) Applicant: DISCO CORPORATION, Tokyo (JP)

(72) Inventor: Shohei OGAWA, Tokyo (JP)

(21) Appl. No.: 19/185,614

(22) Filed: Apr. 22, 2025

(30) Foreign Application Priority Data
May 22, 2024 (JP) 2024-083374
Jun. 17, 2024 (JP) 2024-097283

(51) Int. Cl. B24D 18/00; B24B 53/12; B24D 3/28

(52) U.S. Cl. CPC B24D 18/0009; B24B 53/12; B24D 3/28

(57) ABSTRACT

A method of manufacturing a grindstone includes molding a mixture of materials including abrasive grains, an epoxy resin, and an amine-based hardener to a predetermined shape and leaving the mixture to stand until the epoxy resin is hardened by the amine-based hardener in a chemical reaction therewith, and the amine-based hardener has an amine value of 600 mgKOH/g or higher.

### BACKGROUND OF THE INVENTION

### Field of the Invention

The present invention relates to a grindstone for use in processing a workpiece typified by a wafer, a method of manufacturing a grindstone, a dresser board for dressing a grindstone, and a method of manufacturing a dresser board.

### Description of the Related Art

Electronic appliances, typically, cellular phones and personal computers, have device chips including such devices as integrated circuits (ICs) as their indispensable components. Device chips are fabricated from a wafer made of silicon (Si), for example, by demarcating a plurality of areas on the face side of the wafer with a grid of straight projected dicing lines established thereon, constructing devices respectively in the areas, and dividing the wafer along the projected dicing lines into small pieces that will be used as device chips, for example.

A plate-shaped workpiece typified by a wafer is divided into small pieces by a cutting apparatus having a cutting tool referred to as a cutting blade that includes an annular grindstone and a spindle on which the cutting tool is mounted (see, for example, JP 2003-234308A). When the cutting apparatus is in operation, the cutting blade is rotated about its own central axis at a high speed and forced to cut through the workpiece along projected dicing lines while being supplied with liquid such as water, one at a time, thereby dividing the workpiece along the projected dicing lines into small pieces.

Recent years have seen a growing trend towards more opportunities for thinning down workpieces to meet more sophisticated demands for electronic appliances. A workpiece is thinned down by a grinding apparatus having a grinding tool referred to as a grinding wheel that includes a plurality of cuboid grindstones and a spindle on which the grinding tool is mounted (see, for example, JP 2006-1007A). When the grinding apparatus is in operation, the grinding wheel is rotated about its own central axis and the grindstones are brought into abrasive contact with the workpiece while the grinding wheel is being supplied with liquid such as water, thereby grinding the workpiece to thin down same. Device chips that are manufactured from the workpiece thus thinned down are thin and lightweight.

Grindstones for use in cutting and grinding processes have a structure in which abrasive grains made of diamond, for example, are dispersed and bound in a binder made of a material selected from resin, metal, or ceramic. In general, a phenolic resin that is of excellent mechanical strength is used as the resin of the binder. For fabricating a grindstone using a binder of phenolic resin, for example, powder of a phenolic resin is mixed with abrasive grains, and a mold is filled with the mixture. Then, the mixture is processed by way of hot compression and sintering, thereby producing a grindstone. Grindstones having resin as a binder are referred to as resin-bonded grindstones.

### SUMMARY OF THE INVENTION

When grindstones are fabricated using resin as a binder, hot compression and sintering processes need to be performed as described above. As these processes require a substantial expenditure of energy and energy-related cost, the conventional grindstone fabrication remains to be improved in terms of energy consumption. In addition, dresser boards for use in dressing the grindstones described above have been manufactured in the same manner as the grindstones. Accordingly, the conventional dresser board fabrication also remains to be improved in terms of energy consumption.

Therefore, it is an object of the present invention to provide a method of manufacturing a grindstone that is more advantageous in terms of energy consumption than a conventional method of manufacturing a grindstone that uses resin as a binder and a method of manufacturing a dresser board that is more advantageous in terms of energy consumption than a conventional method of manufacturing a dresser board.

In accordance with an aspect of the present invention, there is provided a method of manufacturing a grindstone. The method includes molding a mixture of materials including abrasive grains, an epoxy resin, and an amine-based hardener to a predetermined shape and leaving the mixture to stand until the epoxy resin is hardened by the amine-based hardener in a chemical reaction therewith. The amine-based hardener has an amine value of 600 mgKOH/g or higher.

In the method of manufacturing a grindstone, preferably, the amine-based hardener is a triamine-based hardener. Preferably, the mixture is left to stand in an environment characterized by a pressure of 1 MPa or lower and a temperature of 150° C. or lower. The mixture may be molded to an annular shape or a cuboid shape.

In accordance with another aspect of the present invention, there is provided a grindstone including abrasive grains and a binder in which the abrasive grains are dispersed and bound. The binder includes resin made of an epoxy resin hardened by an amine-based hardener whose amine value is 600 mgKOH/g or higher in a chemical reaction therewith.

In the grindstone, preferably, the amine-based hardener is a triamine-based hardener.

In accordance with a further aspect of the present invention, there is provided a method of manufacturing a dresser board. The method includes molding a mixture of materials including abrasive grains, an epoxy resin, and an amine-based hardener to a predetermined shape and leaving the mixture to stand until the epoxy resin is hardened by the amine-based hardener in a chemical reaction therewith. The amine-based hardener has an amine value of 600 mgKOH/g or higher.

In the method of manufacturing a dresser board, preferably, the amine-based hardener is a triamine-based hardener. Preferably, the mixture is left to stand in an environment characterized by a pressure of 1 MPa or lower and a temperature of 150° C. or lower. The mixture may be molded to a plate shape.

In accordance with a still further aspect of the present invention, there is provided a dresser board including abrasive grains and a binder in which the abrasive grains are dispersed and bound. The binder includes resin made of an epoxy resin hardened by an amine-based hardener whose amine value is 600 mgKOH/g or higher in a chemical reaction therewith.

In the dresser board, preferably, the amine-based hardener is a triamine-based hardener.

In the method of manufacturing a grindstone according to the aspect of the present invention, inasmuch as the epoxy resin is hardened by the amine-based hardener whose amine value is 600 mgKOH/g or higher in a chemical reaction therewith, the grindstone can be manufactured without heat and pressure necessarily applied from external sources. The method of manufacturing a grindstone according to the aspect of the present invention is more advantageous in terms of energy consumption than the conventional method of manufacturing a grindstone that uses a phenolic resin as a binder.

Similarly, in the method of manufacturing a dresser board according to the further aspect of the present invention, inasmuch as the epoxy resin is hardened by the amine-based hardener whose amine value is 600 mgKOH/g or higher in a chemical reaction therewith, the dresser board can be manufactured without heat and pressure necessarily applied from external sources. The method of manufacturing a dresser board according to the further aspect of the present invention is more advantageous in terms of energy consumption than the conventional method of manufacturing a dresser board that uses a phenolic resin as a binder.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically illustrating the structure of a washer-type cutting blade;

FIG. 2 is a perspective view schematically illustrating the general makeup of a cutting apparatus;

FIG. 3 is a fragmentary cross-sectional view schematically illustrating a portion of a grindstone after an epoxy resin has been hardened by an amine-based hardener, both as materials of the grindstone;

FIG. 4 is a fragmentary cross-sectional view schematically illustrating the portion of the grindstone that has been finished;

FIG. 5 is a graph illustrating the relation between the amine value of the amine-based hardener and the ease with which the grindstone is consumed;

FIG. 6 is a perspective view schematically illustrating the structure of a hub-type cutting blade;

FIG. 7 is a perspective view schematically illustrating the general makeup of a grinding wheel and a grinding apparatus; and

FIG. 8 is a perspective view schematically illustrating the structure of a dresser board.

### DETAILED DESCRIPTION OF THE PREFERRED EMBODIMENT

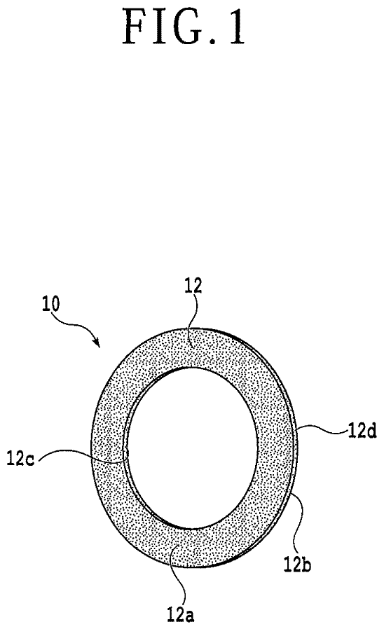

A preferred embodiment of the present invention will be described in detail below with reference to the accompanying drawings. FIG. 1 schematically illustrates the structure of a washer-type cutting blade 10. As illustrated in FIG. 1, the cutting blade 10 includes only an annular grindstone 12 that functions as a cutting edge in its entirety for use in a cutting process.

The grindstone 12 has a first surface 12a and a second surface 12b, each of an annular shape, that lie essentially parallel to each other and essentially flatwise. The first surface 12a and the second surface 12b have respective radially inner edges joined to each other by an inner side face 12c that is commensurate in shape with the side face of a cylinder. The first surface 12a and the second surface 12b also have respective radially outer edges joined to each other by an outer side face 12d that is commensurate in shape with the side face of a cylinder.

The inner side face 12c that joins the radially inner edges of the first surface 12a and the second surface 12b to each other defines a through hole that extends centrally through the grindstone 12 from the first surface 12a to the second surface 12b. When the cutting blade 10 is mounted on a spindle as a rotatable shaft, a portion of a support fixed to the spindle is inserted through the through hole.

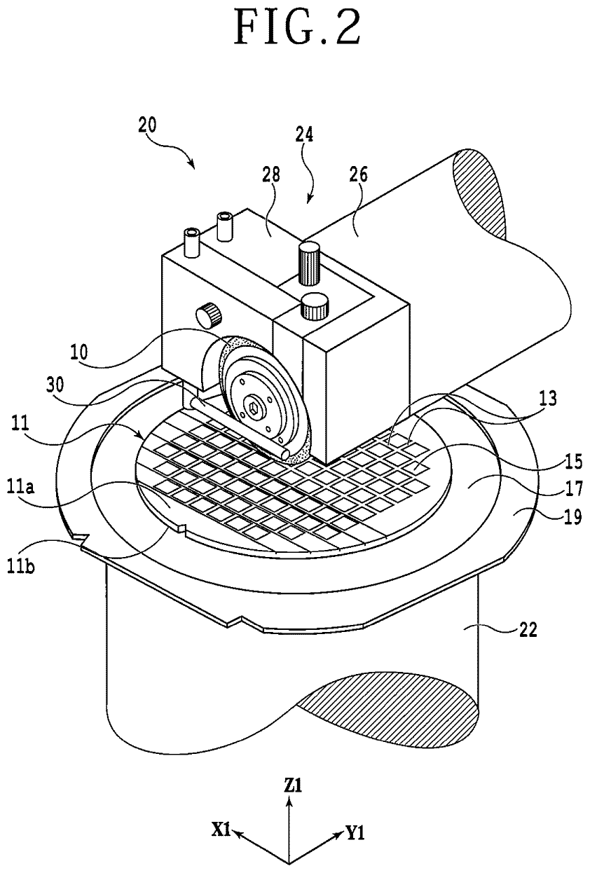

FIG. 2 schematically illustrates the general makeup of a cutting apparatus 20 incorporating the cutting blade 10 therein. FIG. 2 also illustrates an X1-axis indicated by an arrow X1, i.e., a first horizontal axis, a Y1-axis indicated by an arrow Y1, i.e., a second horizontal axis, and a Z1-axis indicated by an arrow Z1, i.e., a vertical axis, extending perpendicularly to each other. The cutting apparatus 20 will be described below in reference to the X1-axis, the Y1-axis, and the Z1-axis wherever necessary. When the cutting apparatus 20 is in operation, the cutting blade 10 is rotated about its own central axis by the spindle and is forced to cut through a workpiece 11, cutting the workpiece 11.

The workpiece 11 is, for example, a disk-shaped wafer made of a material selected from Si, gallium arsenide (GaAs), indium phosphide (InP), gallium nitride (GaN), and silicon carbide (SiC). The workpiece 11 has a first surface 11a and a second surface 11b, each of a circular shape, that lie essentially parallel to each other.

The first surface 11a of the workpiece 11 has a plurality of rectangular areas demarcated by a grid of intersecting streets, i.e., projected dicing lines, 13. Devices 15 such as ICs, for example, are constructed respectively in the areas. When the workpiece 11 is cut and divided along the streets 13, the workpiece 11 produces a plurality of device chips including the respective devices 15.

The workpiece 11 is not limited to the material, shape, structure, and size described and/or illustrated. The workpiece 11 may be a substrate made of such a material as another semiconductor, ceramic, resin, or metal, for example. Similarly, the devices 15 are not limited to the type, quantity, shape, structure, size, and layout described and/or illustrated. The workpiece 11 may even be free of the devices 15.

According to the present embodiment, a circular tape, also known as a dicing tape, 17 that is larger in diameter than the workpiece 11 is affixed to the second surface 11b of the workpiece 11. The tape 17 has an outer edge portion to which an annular frame 19 is secured in surrounding relation to the workpiece 11. Since the workpiece 11 is supported on the frame 19 by the tape 17, the workpiece 11 can be handled with ease. However, the workpiece 11 may not necessarily be supported on the frame 19.

The workpiece 11 as it is supported on the frame 19 is introduced into the cutting apparatus 20 and cut by the cutting apparatus 20. The cutting apparatus 20 includes a chuck table, i.e., a holding table, 22 for holding the workpiece 11 thereon when the workpiece 11 is cut. The chuck table 22 has a circular upper surface that lies essentially parallel to the X1-axis and the X2-axis and essentially flatwise and that supports the workpiece 11 from below.

The upper surface of the chuck table 22 is fluidly connected to an unillustrated suction source such as an ejector, for example, through an unillustrated fluid channel defined in the chuck table 22 and an unillustrated valve. The chuck table 22 is coupled to an unillustrated ball-screw-type chuck table moving mechanism for moving the chuck table 22 along the X1-axis and an unillustrated rotary actuator such as an electric motor, for example, for rotating the chuck table 22 about a rotational axis along the Z1-axis.

The cutting apparatus 20 also includes a cutting unit 24 disposed above the chuck table 22. The cutting unit 24 includes a tubular housing 26 that houses therein an unillustrated cylindrical spindle whose longitudinal axis extends along the Y1-axis. The spindle has a distal end exposed out of the housing 26 and a proximal end coupled to an unillustrated rotary actuator such as an electric motor, for example.

The cutting blade 10 is mounted on the distal end of the spindle by a support jig. The cutting blade 10 thus mounted on the distal end of the spindle has its plane extending along the X1-axis. When the rotary actuator coupled to the spindle is energized, the spindle is rotated about its rotational axis, causing the cutting blade 10 mounted on the distal end of the spindle to be rotated about its central axis along the Y1-axis by the rotary power transmitted from the rotary actuator via the spindle.

The cutting blade 10 mounted on the distal end of the spindle is partly covered with a blade cover 28 fixed to the housing 26. The blade cover 28 supports a pair of nozzles 30 that are positioned one on each side of the cutting blade 10 along the Y1-axis. The nozzles 30 have respective unillustrated ejection ports that are open toward the cutting blade 10, and are able to eject processing liquid such as pure water, for example, to the cutting blade 10. When the cutting apparatus 20 cuts the workpiece 11 on the chuck table 22, the nozzles 30 eject the processing liquid to the cutting blade 10. The processing liquid thus supplied from the nozzles 30 to the cutting blade 10 flows down to the workpiece 11 and hence cools the cutting blade 10 and also the workpiece 11 and washes away swarf produced while the workpiece 11 is being cut by the cutting blade 10.

The cutting unit 24 is coupled to an unillustrated ball-screw-type cutting unit moving mechanism for moving the cutting unit 24. The cutting unit moving mechanism is able to move the cutting unit 24 along the Y1-axis and also to move the cutting unit 24 along the Z1-axis, i.e., to selectively lift and lower the cutting unit 24. The cutting unit moving mechanism can thus adjust the position of the cutting blade 10 along the Y1-axis and the position of the cutting blade 10 along the Z1-axis.

For cutting the workpiece 11 on the cutting apparatus 20, initially, the workpiece 11 is placed and held on the chuck table 22. For example, the workpiece 11 is placed on the chuck table 22 such that the first surface 11a faces upwardly and the second surface 11b, i.e., the tape 17 affixed to the second surface 11b, faces the upper surface of the chuck table 22. Then, the suction source that is fluidly connected to the chuck table 22 is actuated to apply a suction force, i.e., a negative pressure, to the upper surface of the chuck table 22. The workpiece 11 on the upper surface of the chuck table 22 is now attracted under suction to the chuck table 22 with the tape 17 interposed therebetween and is held securely on the chuck table 22.

Then, the orientation of the chuck table 22 about the Z1-axis is adjusted to make those streets 13 that are to be cut along oriented parallel to the X1-axis. In addition, the positional relation between the chuck table 22 and the cutting unit 24 is adjusted to position the cutting blade 10 above a target one of the streets 13 oriented parallel to the X1-axis.

Thereafter, the height of the cutting unit 24 is adjusted such that the cutting blade 10 has its lower end positioned slightly below the second surface 11b, i.e., the upper surface of the tape 17, of the workpiece 11. Then, while the rotary actuator coupled to the spindle is rotating the spindle and hence the cutting blade 10, the chuck table moving mechanism moves, i.e., processing-feeds, the chuck table 22 along the X1-axis.

The cutting blade 10 and the workpiece 11 now move relatively to each other along the X1-axis, so that the cutting blade 10 cuts through the workpiece 11 along the target street 13 (at the target street 13). As a result, the workpiece 11 is severed and divided along the target street 13 (at the target street 13) by the cutting blade 10. The cutting process described above is repeated to divide the workpiece 11 along all the streets 13 (at all the streets 13), producing a plurality of device chips each including one of the devices 15.

The workpiece 11 may be cut in various different forms. According to the above cutting process, the cutting blade 10 cuts through the workpiece 11 all the way across the entire depth of the workpiece 11. However, the cutting blade 10 may cut into the workpiece 11 to a depth terminating short of the second surface 11b thereof, thereby forming a groove that extends into the workpiece 11 from the first surface 11a and that has a depth smaller than the entire depth (thickness) of the workpiece 11 (half-cutting process).

The cutting blade 10 according to the present embodiment may be manufactured according to the following manufacturing process, for example. First, abrasive grains, an epoxy resin, and an amine-based hardener as materials of the cutting blade 10 are mixed together at a normal temperature in the range of 0° C. to 40° C. (mixing step). The abrasive grains are grains of diamond or cubic boron nitride (cBN), for example, and each typically have a maximum width ranging approximately from 0.1 μm to 140 μm.

The epoxy resin is liquid at the normal temperature and may be a bisphenol-A epoxy resin, a bisphenol-B epoxy resin, or an aliphatic epoxy resin, for example. It is especially preferable to use an epoxy resin having a low epoxy equivalent weight and many epoxy groups in molecules.

The amine-based hardener has an amine value of 600 mgKOH/g or higher, preferably of 800 mgKOH/g or higher. The amine value refers to a value representing the number of milligrams of potassium hydroxide equivalent to an acid required to neutralize one gram of a specimen, i.e., the amine-based hardener.

By using the amine-based hardener whose amine value is 600 mgKOH/g or higher, the grindstone 12 whose performance is equivalent to or better than conventional grindstones that use powder of a phenolic resin and that are produced by the hot compression and sintering processes can be obtained without being treated in the hot compression and sintering processes. For example, the grindstone 12 manufactured by a manufacturing method according to the present embodiment has durability, i.e., consumption resistance, equivalent to or better than conventional grindstones.

The amine-based hardener may be a triamine-based hardener, for example. Specific examples of the triamine-based hardener include diethylene triamine, 4-dodecyl diethylene triamine, triethylene tetramine, hexamethylene tetramine, tetraethylene pentaamine, pentaethylene hexamine, and diethylaminopropylamine, for example. It is especially preferable to use diethylene triamine having features including a high amine value.

An optional additive may be added as a material of the cutting blade 10 in addition to the abrasive grains, the epoxy resin, and the amine-based hardener. The type and amount of the additive may be selected appropriately pursuant to the performance that the cutting blade 10 is required to have.

After the materials including the abrasive grains, the epoxy resin, and the amine-based hardener have been mixed together, the mixture is molded to a desired shape (molding step). The mixture may be molded according to any of desired processes. For example, a mold may be filled with the mixture or the space between two films that are spaced from each other may be filled with the mixture, to thereby mold the mixture to a desired shape.

According to the present embodiment, the mixture is molded to an annular shape commensurate with the shape of the grindstone 12 of the cutting blade 10. If a period of time represented by 24 hours or longer elapses after the amine-based hardener has been mixed with the epoxy resin, the hardening of the mixture progresses to the extent that its flowability is greatly reduced. Consequently, it is preferable to carry out the molding step before the hardening of the mixture progresses to a certain extent after the mixing step, i.e., within 12 hours after the mixing step.

After the mixture has been molded to the desired shape, it is left to stand until the epoxy resin is fully hardened by a chemical reaction with the amine-based hardener (hardening step). The period of time required for the epoxy resin to be fully hardened is typically 12 hours or longer though it varies depending on the specific materials used. The environment in which to harden the epoxy resin needs to be at least more advantageous in terms of consumed energy and energy-related cost than if the hot compression and sintering processes are involved.

Specifically, the epoxy resin is hardened by the amine-based hardener in an environment characterized by a lower pressure and a lower temperature than those in the hot compression and sintering processes, i.e., an environment characterized by a pressure of 1 MPa or lower and a temperature of 150° C. or lower. It is possible for the epoxy resin to be hardened by the amine-based hardener without being subjected to pressure and heat. It is thus more preferable for the epoxy resin to be hardened by the amine-based hardener in an environment at the normal temperature and a normal pressure in the range of 900 hPa to 1050 hPa.

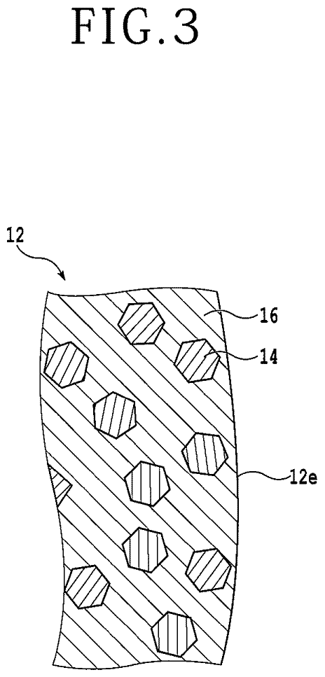

FIG. 3 schematically illustrates in fragmentary cross section a portion of the grindstone 12 after the epoxy resin has been hardened by the amine-based hardener, both as materials of the grindstone 12. As illustrated in FIG. 3, the grindstone 12 manufactured by the above process is of a structure in which a plurality of abrasive grains 14 are dispersed and bound in a binder 16 made of resin obtained by a chemical reaction between the epoxy resin and the amine-based hardener. In the grindstone 12 as it is fabricated, almost no abrasive grains are exposed on a surface 12e such as the outer side face 12d of the grindstone 12.

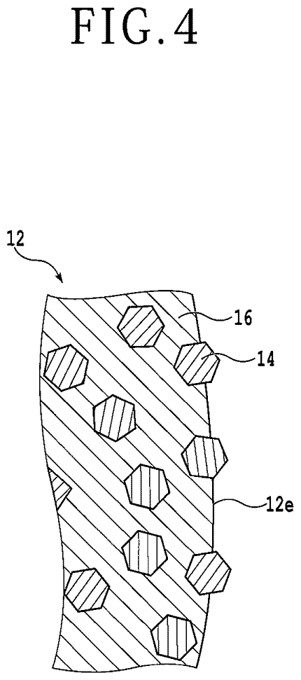

After the epoxy resin has been hardened by the amine-based hardener, the grindstone 12 is finished to a state suitable for the cutting process on the cutting apparatus 20 (finishing step). Specifically, the grindstone 12 as it is rotating is caused to cut into a dresser board, for example, that is of a structure in which abrasive grains are dispersed in a binder, until the grindstone 12 is slightly consumed. The grindstone 12 finished, i.e., dressed, by the dresser board has some abrasive grains 14 exposed on the surface 12e of the grindstone 12, as illustrated in FIG. 4. FIG. 4 schematically illustrates the portion of the grindstone 12 that has been finished.

The finishing step may be carried out on the grindstone 12 immediately before the cutting blade 10 is used to cut the workpiece 11. Stated otherwise, the finishing step may not necessarily be included in the method of manufacturing the grindstone 12.

An experiment was conducted to confirm the ease with which the grindstone 12 thus manufactured is consumed. Specifically, after the grindstone 12 of the cutting blade 10 was caused to cut into a dresser board while the cutting blade 10 was rotating, the amount of consumption of the grindstone 12, i.e., the reduction in the diametrical dimension of the cutting blade 10, was measured.

The experiment was conducted on two grindstones 12 according to inventive examples and three grindstones according to comparative examples. One of the two grindstones 12 according to inventive examples was manufactured using an amine-based hardener with an amine value of 600 mgKOH/g, and the other grindstone 12 was manufactured using an amine-based hardener with an amine value of 800 mgKOH/g. One of the three grindstones according to the comparative examples was a conventional grindstone using a binder of a phenolic resin and processed by way of hot compression and sintering. Another one was a grindstone manufactured using an amine-based hardener with an amine value of 400 mgKOH/g, and the last one was a grindstone manufactured using an amine-based hardener with an amine value of 500 mgKOH/g. These grindstones according to the comparative examples were treated and measured in the same manner as the grindstones 12 according to the inventive examples.

The grindstones 12 according to the inventive examples contained a bisphenol-A epoxy resin, a triamine-based hardener, and abrasive grains of diamond having an average particle diameter of 20 μm (#600). The average particle diameter used herein refers to a particle diameter at a cumulative value of 50% in a particle diameter distribution measured by a laser diffraction scattering process (median diameter; d50; 50% diameter).

The inner side face 12c of each of the grindstones 12 had a diameter of 40 mm, the outer side faces 12d of each of the grindstones 12 had a diameter of 54 mm, and the distance between the first surface 12a and the second surface 12b of each of the grindstones 12, i.e., the thickness of each of the grindstones 12, was 0.2 mm. The grindstones according to the comparative examples had the same materials, dimensions, etc. as the grindstones 12, except that the conventional grindstone used a phenolic resin instead of an epoxy resin and an amine-based hardener.

In the experiment, a resin blade manufactured by DISCO Corporation was used as the conventional grindstone. The dresser board contained abrasive grains having an average particle diameter of 12 μm (#1000). The dresser board had a length of 75 mm, a width of 75 mm, and a thickness of 1.0 mm.

For causing the grindstones 12 to cut into the dresser board, the rotational speed per unit time for the spindle was set to 20000 rpm and the speed at which the grindstones 12 were processing-fed was set to 10 mm/s. The number of times that the grindstones 12 were caused to cut into the dresser board, i.e., the number of grooves formed in the dresser board by the grindstones 12 as they cut into the dresser board, was set to 10.

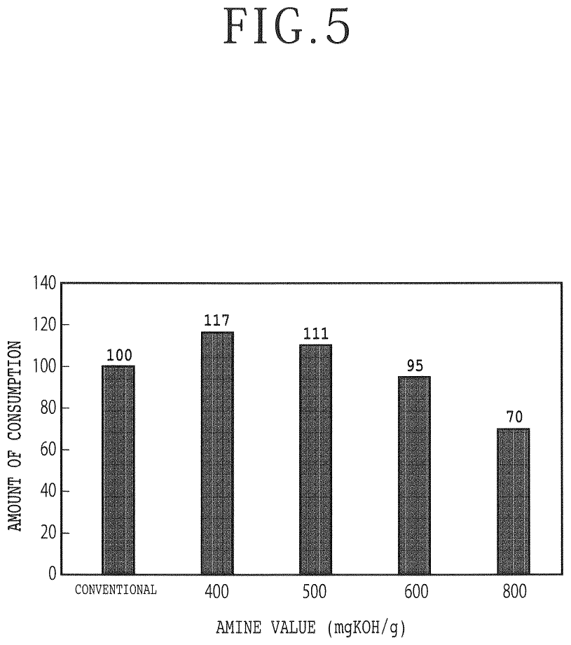

FIG. 5 is a graph illustrating the results of the experiment, i.e., the relation between the amine value of the amine-based hardener and the ease with which each of the grindstones is consumed. The graph has a horizontal axis representing the amine values of the amine-based hardeners used in the respective grindstones, indicative of the types of the grindstones, and a vertical axis representing the amounts of consumption of the respective grindstones in comparison with 100 as the amount of consumption of the conventional grindstone.

A study of FIG. 5 reveals that the grindstones 12 according to the inventive examples that were manufactured using the amine-based hardeners whose amine values were 600 mgKOH/g or higher had smaller amounts of consumption than the conventional grindstone manufactured using the phenolic resin. In other words, the grindstones 12 according to the inventive examples had a higher level of durability, i.e., consumption resistance, than the conventional grindstone.

The method of manufacturing a grindstone according to the present embodiment is capable of manufacturing the grindstone 12 without heat and pressure necessarily applied from external sources because the epoxy resin is hardened by a chemical reaction with an amine-based hardener having an amine value of 600 mgKOH/g or higher. In other words, the method of manufacturing a grindstone according to the present embodiment is more advantageous in terms of energy consumption than the conventional method of manufacturing a grindstone that uses a phenolic resin as a binder.

Further, since the method of manufacturing a grindstone according to the present embodiment uses an amine-based hardener having an amine value of 600 mgKOH/g or higher or preferably an amine-based hardener having an amine value of 800 mgKOH/g or higher, the method is able to produce the grindstone 12 that is of excellent durability compared with the conventional method of manufacturing a grindstone that uses a phenolic resin as a binder.

The present invention is not limited to the embodiment described above, and various changes and modifications may be made therein. For example, while the washer-type cutting blade 10 that includes the annular grindstone 12 only has been described above according to the above embodiment, the present invention is also applicable to a method of manufacturing a grindstone for use in a hub-type cutting blade according to a modification.

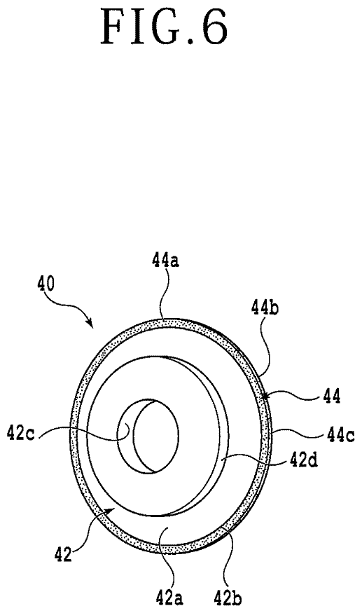

FIG. 6 schematically illustrates in perspective the structure of a hub-type cutting blade 40. As illustrated in FIG. 6, the hub-type cutting blade 40 includes an annular blade base 42. The blade base 42 is made of such metal as an aluminum alloy, for example, and has a first surface 42a and a second surface 42b that faces away from the first surface 42a.

The blade base 42 has a through circular hole 42c that is defined centrally therein and that extends through the blade base 42 from the first surface 42a to the second surface 42b. The blade base 42 also has an annular land 42d protruding from the first surface 42a around the hole 42c.

The cutting blade 40 also includes an annular grindstone 44 secured to the second surface 42b of the blade base 42 along an outer circumferential edge of the blade base 42. The grindstone 44 is of the same structure and is manufactured by the same manufacturing method as the grindstone 12 described above. Specifically, the grindstone 44 has a first surface 44a and a second surface 44b, each of an annular shape, that lie essentially parallel to each other and essentially flatwise. The first surface 44a and the second surface 44b have respective radially outer edges joined to each other by an outer side face 44c that is commensurate in shape with the side face of a cylinder.

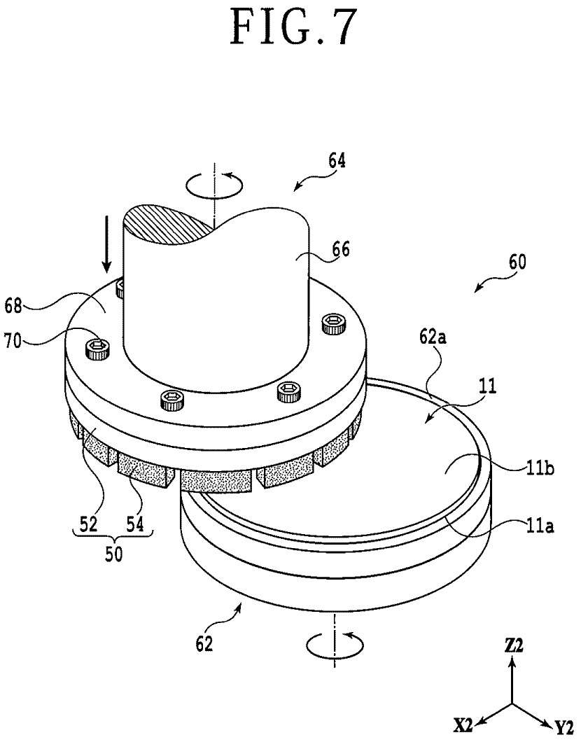

The method of manufacturing the grindstones according to the above embodiment and modification is also applicable to manufacturing a tool for use in a grinding process. FIG. 7 schematically illustrates in perspective a grinding wheel 50 as a tool for use in a grinding process. As illustrated in FIG. 7, the grinding wheel 50 includes an annular wheel base 52 made of such metal as aluminum or stainless steel, for example.

The wheel base 52 has a lower surface on which there are mounted a plurality of grindstones 54, each of a cuboid shape, for use in a grinding process. The grindstones 54 are arranged in an annular array and spaced at essentially equal intervals circumferentially around the wheel base 52. Each of the grindstones 54 is manufactured by the method of manufacturing a grindstone according to the above embodiment. However, the grindstones 54 may be of any desired shape, structure, size, and in a desired quantity.

The grinding wheel 50 is installed in and used on a grinding apparatus 60 illustrated in FIG. 7. FIG. 7 also illustrates an X2-axis indicated by an arrow X2, i.e., a first horizontal axis, a Y2-axis indicated by an arrow Y2, i.e., a second horizontal axis, and a Z2-axis indicated by an arrow 22, i.e., a vertical axis, extending perpendicularly to each other. The grinding apparatus 60 will be described below in reference to the X2-axis, the Y2-axis, and the Z2-axis wherever necessary.

The grinding apparatus 60 includes a chuck table, i.e., a holding table, 62 for holding the workpiece 11 thereon when the workpiece 11 is ground. The chuck table 62 has an upper surface 62a having a shape commensurate with the side face of a cone. The upper surface 62a has a center aligned with the vertex of the cone and an outer circumferential edge extending around the center. The difference between the heights of the center and the outer circumferential edge of the upper surface 62a is approximately in the range of 10 μm to 30 μm.

The upper surface of the chuck table 62 is fluidly connected to an unillustrated suction source such as an ejector, for example, through an unillustrated fluid channel defined in the chuck table 62 and an unillustrated valve. The chuck table 62 is coupled to an unillustrated chuck table moving mechanism for moving the chuck table 62 along the X2-axis and the Y2-axis and an unillustrated rotary actuator such as an electric motor, for example, for rotating the chuck table 62 about a rotational axis along the Z2-axis.

The grinding apparatus 60 also includes a grinding unit 64 disposed above the chuck table 62. The grinding unit 64 includes an unillustrated tubular housing that houses therein a cylindrical spindle 66 whose longitudinal axis extends along the Z2-axis. The spindle 66 has a distal end exposed out of the housing and a proximal end coupled to an unillustrated rotary actuator such as an electric motor, for example.

A disk-shaped wheel mount 68 made of aluminum or stainless steel, for example, is secured to the distal end of the spindle 66 that is exposed out of the housing. The wheel mount 68 has a lower surface on which the grinding wheel 50 is detachably mounted by fasteners 70 such as bolts, for example.

When the rotary actuator coupled to the spindle 66 is energized, the spindle 66 and hence the grinding wheel 50 mounted on the distal end of the spindle 66 are rotated about a rotational axis along the Z2-axis by the rotary power transmitted from the rotary actuator via the spindle 66. When the grinding wheel 50 is rotated, the grindstones 54 are turned about the rotational axis of the spindle 66 along an annular path parallel to the X2-axis and the Y2-axis.

The grinding unit 64 is coupled to an unillustrated ball-screw-type grinding unit moving mechanism for moving the grinding unit 64 along the Z2-axis, i.e., for selectively lifting and lowering the grinding unit 64. When the grinding unit moving mechanism lifts or lowers the grinding unit 64, the grinding wheel 50 is moved away from or toward the chuck table 62.

An unillustrated nozzle for supplying processing liquid such as pure water, for example, is disposed in or near the grinding unit 64. When the grinding wheel 50 grinds the workpiece 11 on the chuck table 62, the nozzle ejects the processing liquid toward the workpiece 11 and the grindstones 54, thereby cooling the workpiece 11 and the grindstones 54 and washing away swarf produced while the workpiece 11 is being ground by the grinding wheel 50.

For grinding the workpiece 11 on the grinding apparatus 60, initially, the workpiece 11 is placed and held on the chuck table 62. For example, the workpiece 11 is placed on the chuck table 62 such that the second surface 11b faces upwardly and the first surface 11a faces the upper surface 62a of the chuck table 62. Then, the suction source that is fluidly connected to the chuck table 62 is actuated to apply a suction force, i.e., a negative pressure, to the upper surface 62a of the chuck table 62. The workpiece 11 on the upper surface 62a of the chuck table 62 is now attracted under suction to the chuck table 62 and is held securely on the chuck table 62. A protective tape, for example, for protecting the workpiece 11 may be affixed to the first surface 11a of the workpiece 11.

Then, the positional relation between the chuck table 62 and the grinding unit 64 is adjusted.

Specifically, the positional relation between the chuck table 62 and the grinding unit 64 is adjusted along the X2-axis and the Y2-axis in order to bring the path to be followed by the grindstones 54 into vertical alignment with the center of the workpiece 11 on the chuck table 62 along a direction that is essentially perpendicular to the upper surface 62a of the chuck table 62.

Thereafter, the rotary actuator coupled to the spindle 66 is energized to rotate the spindle 66 and hence the grinding wheel 50, and the rotary actuator coupled to the chuck table 62 is energized to rotate the chuck table 62. Then, the grinding unit moving mechanism lowers the grinding unit 64 at a predetermined speed to move the grinding wheel 50 closer to the workpiece 11 on the chuck table 62. When the grindstones 54 are brought into abrasive contact with the second surface 11b of the workpiece 11, the grindstones 54 grind the workpiece 11.

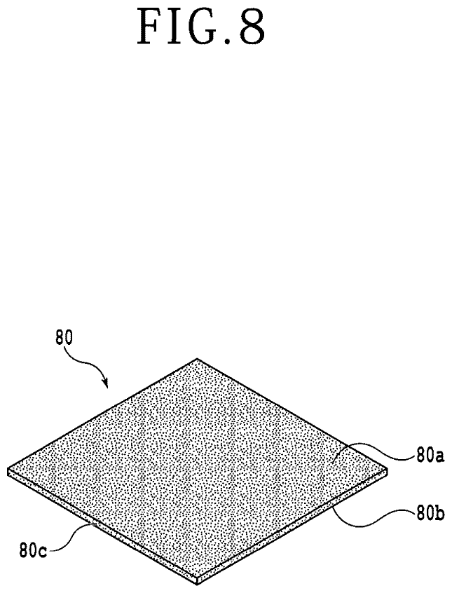

A dresser board for dressing, i.e., restoring the original abrasive grain sharpness of, grindstones may be manufactured in the same sequence of steps as the method of manufacturing the grindstones according to the above embodiment and modification. FIG. 8 schematically illustrates in perspective the structure of a dresser board 80. As with the grindstones 12 and 54, the dresser board 80 is of a structure in which abrasive grains are dispersed and bound in a binder made of resin obtained from an epoxy resin hardened by an amine-based hardener in a chemical reaction therewith.

As illustrated in FIG. 8, the dresser board 80 has a first surface 80a and a second surface 80b, each of a rectangular shape, that lie essentially parallel to each other and essentially flatwise. The first surface 80a and the second surface 80b have outer edges joined to each other by four rectangular side faces 80c. In other words, the dresser board 80 is shaped as a rectangular flat plate as viewed in plan. The dresser board 80 typically has a length of 75 mm, a width of 75 mm, and a thickness of 1.0 mm. However, the dresser board 80 is not limited to the shape and size described and illustrated.

When the dresser board 80 is in use, the second surface 80b thereof is held on an unillustrated chuck table, for example, and a grindstone to be dressed is brought into contact with, i.e., caused to cut into, the first surface 80a of the dresser board 80. In this manner, the grindstone is dressed, i.e., is reshaped and has abrasive grains exposed afresh, for example.

The dresser board 80 can be manufactured by the method of manufacturing the grindstones according to the above embodiment and modification. Specifically, abrasive grains, an epoxy resin, and an amine-based hardener as materials of the dresser board 80 are mixed together at the normal temperature in the range of 0° C. to 40° C. (mixing step). Details of the mixing step are the same as those described above according to the embodiment.

After the materials including the abrasive grains, the epoxy resin, and the amine-based hardener have been mixed together, the mixture is molded to a desired shape (molding step). Specifically, the mixture is molded to a flat shape commensurate with the dresser board 80. Other details of the molding step are the same as those described above according to the embodiment.

After the mixture has been molded to the desired shape, it is left to stand until the epoxy resin is fully hardened by a chemical reaction with the amine-based hardener (hardening step). Details of the hardening step are the same as those described above according to the embodiment.

After the epoxy resin has been hardened by the amine-based hardener, the dressing board 80 is finished to a state suitable for dressing grindstones (finishing step). The finishing step for finishing the dressing board 80 may be omitted. Stated otherwise, the finishing step may not necessarily be included in the method of manufacturing a dresser board.

Structural and methodical details according to the embodiment and modification may be changed or modified without departing from the scope of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A method of manufacturing a grindstone, comprising:
molding a mixture of materials including abrasive grains, an epoxy resin, and an amine-based hardener to a predetermined shape; and
leaving the mixture to stand until the epoxy resin is hardened by the amine-based hardener in a chemical reaction therewith,
wherein the amine-based hardener has an amine value of 600 mgKOH/g or higher.

2. The method according to claim 1, wherein the amine-based hardener is a triamine-based hardener.

3. The method according to claim 1, wherein the mixture is left to stand in an environment characterized by a pressure of 1 MPa or lower and a temperature of 150° C. or lower.

4. The method according to claim 1, wherein the mixture is molded to an annular shape or a cuboid shape.

5. The method according to claim 2, wherein the mixture is left to stand in an environment characterized by a pressure of 1 MPa or lower and a temperature of 150° C. or lower.

6. The method according to claim 2, wherein the mixture is molded to an annular shape or a cuboid shape.

7. A grindstone comprising:
abrasive grains; and
a binder in which the abrasive grains are dispersed and bound,
wherein the binder includes resin made of an epoxy resin hardened by an amine-based hardener whose amine value is 600 mgKOH/g or higher in a chemical reaction therewith.

8. The grindstone according to claim 7, wherein the amine-based hardener is a triamine-based hardener.

9. A method of manufacturing a dresser board, comprising:
molding a mixture of materials including abrasive grains, an epoxy resin, and an amine-based hardener to a predetermined shape; and
leaving the mixture to stand until the epoxy resin is hardened by the amine-based hardener in a chemical reaction therewith,
wherein the amine-based hardener has an amine value of 600 mgKOH/g or higher.

10. The method according to claim 9, wherein the amine-based hardener is a triamine-based hardener.

11. The method according to claim 9, wherein the mixture is left to stand in an environment characterized by a pressure of 1 MPa or lower and a temperature of 150° C. or lower.

12. The method according to claim 9, wherein the mixture is molded to a plate shape.

13. The method according to claim 10, wherein the mixture is left to stand in an environment characterized by a pressure of 1 MPa or lower and a temperature of 150° C. or lower.

14. The method according to claim 10, wherein the mixture is molded to a plate shape.

15. A dresser board comprising:
abrasive grains; and
a binder in which the abrasive grains are dispersed and bound,
wherein the binder includes resin made of an epoxy resin hardened by an amine-based hardener whose amine value is 600 mgKOH/g or higher in a chemical reaction therewith.

16. The dresser board according to claim 15,
wherein the amine-based hardener is a triamine-based hardener.
